(19) United States
(12) Patent Application Publication
(10) Pub. No.: US 2010/0108975 A1
(43) Pub. Date: May 6, 2010

(54) NON-VOLATILE MEMORY CELL FORMATION

(75) Inventors: Ming Sun, Eden Prairie, MN (US); Wei Tian, Bloomington, MN (US); Insik Jin, Eagan, MN (US); Michael Xuefei Tang, Bloomington, MN (US); Andrew James Wirebaugh, Hopkins, MN (US)

Correspondence Address: CAMPBELL NELSON WHIPPS, LLC, HISTORIC HAMM BUILDING, 408 SAINT PETER STREET, SUITE 240, ST. PAUL, MN, 55102, US

(73) Assignee: SEAGATE TECHNOLOGY LLC, SCOTTS VALLEY, CA (US)

(21) Appl. No.: 12/265,551

(22) Filed: Nov. 5, 2008

(51) Int. Cl. H01L 45/00

(52) U.S. Cl. 257/4; 438/102; 257/E45.002

(57) ABSTRACT

A method and apparatus for forming a non-volatile memory cell, such as a PMC memory cell. In some embodiments, a first electrode is connected to a source while a second electrode is connected to a ground. An ionic region is located between the first and second electrodes and comprises a doping layer, composite layer, and electrolyte layer. The composite layer has a low resistive state and the electrolyte layer switches from a high resistive state to a low resistive state based on the presence of a filament.

### BACKGROUND

Data storage devices generally operate to store and retrieve data in a fast and efficient manner. Some storage devices utilize a semiconductor array of solid-state memory cells to store individual bits of data. Such memory cells can be volatile (e.g., DRAM, SRAM) or non-volatile (RRAM, STRAM, flash, etc.).

As will be appreciated, volatile memory cells generally retain data stored in memory only so long as operational power continues to be supplied to the device, while non-volatile memory cells generally retain data storage in memory even in the absence of the application of operational power.

In these and other types of data storage devices, it is often desirable to increase efficiency of memory cell formation, particularly with regard to the reading of data from the memory cell.

### SUMMARY

Various embodiments of the present invention are generally directed to a method and apparatus for forming a non-volatile memory cell, such as but not limited to a PCM memory cell.

In accordance with various embodiments, a first electrode is connected to a source while a second electrode is connected to a ground. An ionic region is located between the first and second electrodes and comprises a doping layer, composite layer, and electrolyte layer. The composite layer has a low resistive state and the electrolyte layer switches from a high resistive state to a low resistive state based on the presence of a filament.

In other embodiments, an electrolyte layer is deposited on a first electrode. A composite layer is coupled to the electrolyte layer and a doping layer is deposited onto the composite layer. A second electrode is coupled to the doping layer, wherein the composite layer has a low resistive state and the electrolyte layer that switches between a low resistive state and a high resistive state based on the presence of a filament.

These and various other features and advantages which characterize the various embodiments of the present invention can be understood in view of the following detailed discussion and the accompanying drawings.

### BRIEF DESCRIPTION OF THE DRAWINGS

FIG. 1 is a generalized functional representation of an exemplary data storage device constructed and operated in accordance with various embodiments of the present invention.

FIG. 2 shows circuitry used to read data from and write data to a memory array of the device of FIG. 1.

FIG. 3 generally illustrates a manner in which data can be written to a memory cell of the memory array.

FIG. 4 generally illustrates a manner in which data can be read from the memory cell of FIG. 3.

FIG. 5 shows the operation of a memory cell.

FIG. 6 displays the operation of a memory cell.

FIG. 7 generally illustrates a memory cell operated in accordance with various embodiments of the present invention.

FIG. 8 shows a memory cell operated in accordance with various embodiments of the present invention.

FIG. 9 displays an array of memory cells operated in accordance with various embodiments of the present invention.

FIG. 10 shows a flow diagram for a formation operation performed in accordance with the various embodiments of the present invention.

FIG. 11 sets forth a graphical representation of the flow diagram of FIG. 10 performed in accordance with the various embodiments of the present invention.

### DETAILED DESCRIPTION

FIG. 1 provides a functional block representation of a data storage device 100 constructed and operated in accordance with various embodiments of the present invention. The data storage device is contemplated as comprising a portable non-volatile memory storage device such as a PCMCIA card or USB-style external memory device. It will be appreciated, however, that such characterization of the device 100 is merely for purposes of illustrating a particular embodiment and is not limiting to the claimed subject matter.

Top level control of the device 100 is carried out by a suitable controller 102, which may be a programmable or hardware based microcontroller. The controller 102 communicates with a host device via a controller interface (I/F) circuit 104 and a host I/F circuit 106. Local storage of requisite commands, programming, operational data, etc. is provided via random access memory (RAM) 108 and read-only memory (ROM) 110. A buffer 112 serves to temporarily store input write data from the host device and readback data pending transfer to the host device.

A memory space is shown at 114 to comprise a number of memory arrays 116 (denoted Array 0-N), although it will be appreciated that a single array can be utilized as desired. Each array 116 comprises a block of semiconductor memory of selected storage capacity. Communications between the controller 102 and the memory space 114 are coordinated via a memory (MEM) I/F 118. As desired, on-the-fly error detection and correction (EDC) encoding and decoding operations are carried out during data transfers by way of an EDC block 120.

While not limiting, in some embodiments the various circuits depicted in FIG. 1 are arranged as a single chip set formed on one or more semiconductor dies with suitable encapsulation, housing and interconnection features (not separately shown for purposes of clarity). Input power to operate the device is handled by a suitable power management circuit 122 and is supplied from a suitable source such as from a battery, AC power input, etc. Power can also be supplied to the device 100 directly from the host such as through the use of a USB-style interface, etc.

Any number of data storage and transfer protocols can be utilized, such as logical block addressing (LBAs) whereby data are arranged and stored in fixed-size blocks (such as 512 bytes of user data plus overhead bytes for ECC, sparing, header information, etc). Host commands can be issued in terms of LBAs, and the device 100 can carry out a corresponding LBA-to-PBA (physical block address) conversion to identify and service the associated locations at which the data are to be stored or retrieved.

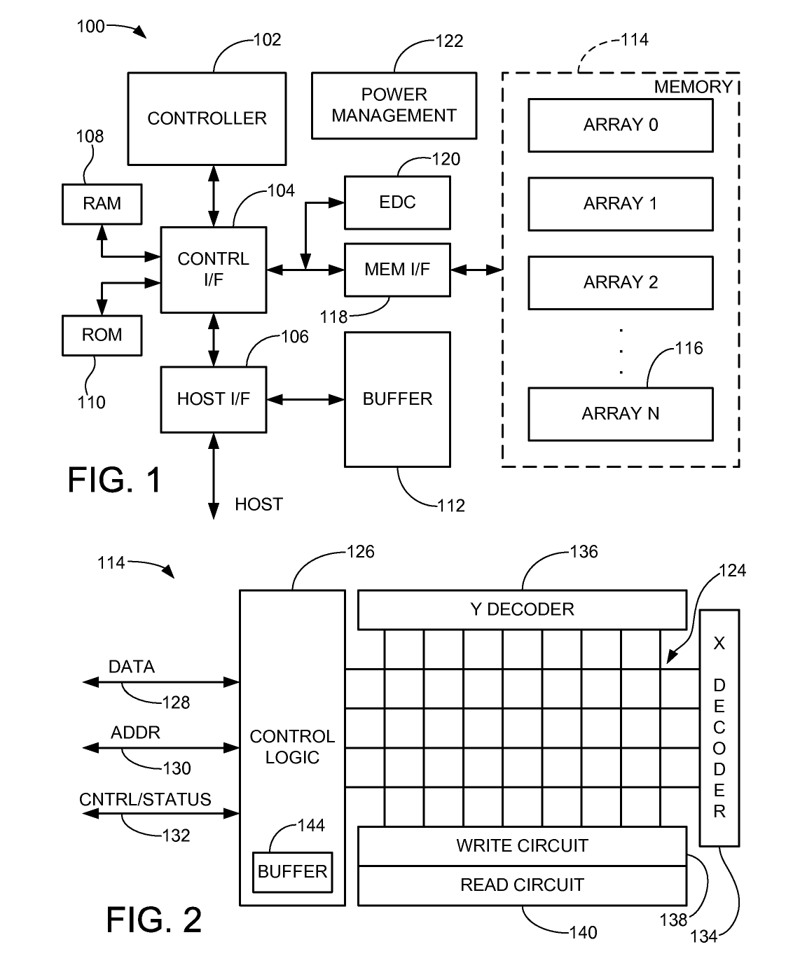

FIG. 2 provides a generalized representation of selected aspects of the memory space 114 of FIG. 1. Data are stored as an arrangement of rows and columns of memory cells 124, accessible by various row (word) and column (bit) lines, etc. In some embodiments, each of the array memory cells 124 has resistive random access memory (RRAM) configuration, such as a programmable metallization cell (PMC) configuration.

The actual configurations of the cells and the access lines thereto will depend on the requirements of a given application. Generally, however, it will be appreciated that the various control lines will generally include enable lines that selectively enable and disable the respective writing and reading of the value(s) of the individual cells.

Control logic 126 receives and transfers data, addressing information and control/status values along multi-line bus paths 128, 130 and 132, respectively. X and Y decoding circuitry 134, 136 provide appropriate switching and other functions to access the appropriate cells 124. A write circuit 138 represents circuitry elements that operate to carry out write operations to write data to the cells 124, and a read circuit 140 correspondingly operates to obtain readback data from the cells 124. Local buffering of transferred data and other values can be provided via one or more local registers 144. At this point it will be appreciated that the circuitry of FIG. 2 is merely exemplary in nature, and any number of alternative configurations can readily be employed as desired depending on the requirements of a given application.

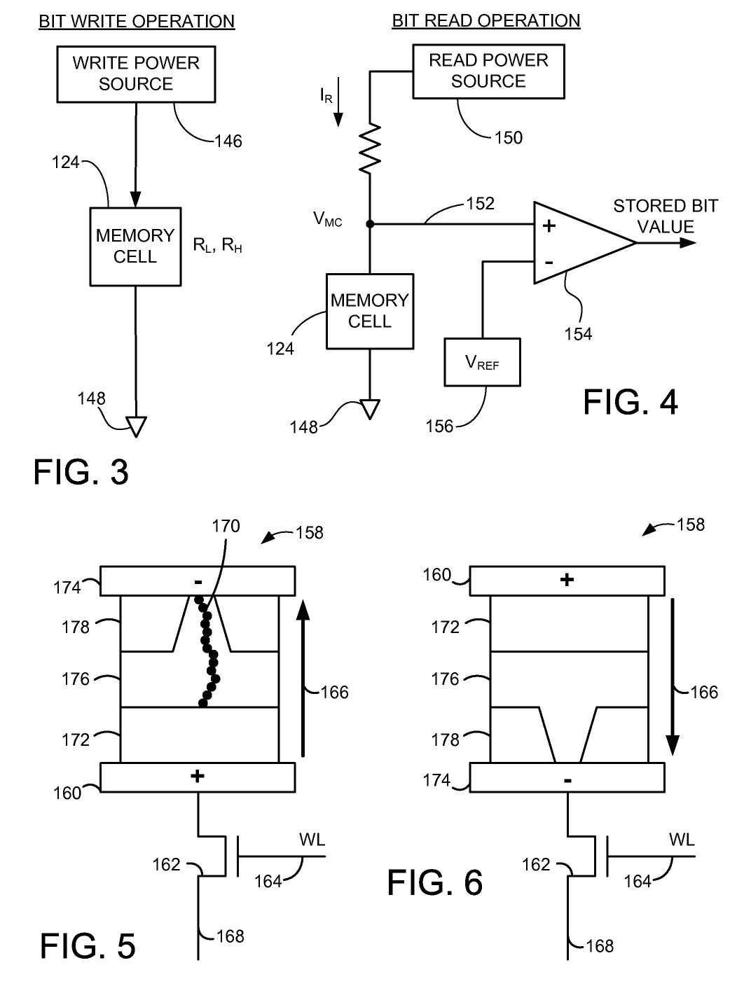

Data are written to the respective memory cells 124 as generally depicted in FIG. 3. Generally, a write power source 146 applies the necessary input (such as in the form of current, voltage, magnetization, etc.) to configure the memory cell 124 to a desired state. It can be appreciated that FIG. 3 is merely a representative illustration of a bit write operation. The configuration of the write power source 146, memory cell 124, and reference node 148 can be suitably manipulated to allow writing of a selected logic state to each cell.

As explained below, in some embodiments the memory cell 124 takes a modified RRAM configuration, in which case the write power source 146 is characterized as a current driver connected through a memory cell 124 to a suitable reference node 148, such as ground. The write power source 146 provides a stream of power by moving through a material in the memory cell 124.

The cell 124 may take either a relatively low resistance (R_{L}) or a relatively high resistance (R_{H}). While not limiting, exemplary R_{L} values may be in the range of about 1000 ohms (Ω) or so, whereas exemplary R_{H} values may be in the range of about 2000Ω or so. Other resistive memory type configurations (e.g., RRAMS) are supplied with a suitable voltage or other input, but provide a much broader range of resistance values (R_{L}˜100Ω and R_{H}·10 MΩ). These values are retained by the respective cells until such time that the state is changed by a subsequent write operation. While not limiting, in the present example it is contemplated that a high resistance value (R_{H}) denotes storage of a logical 1 by the cell 124, and a low resistance value (R_{L}) denotes storage of a logical 0.

The logical bit value(s) stored by each cell 124 can be determined in a manner such as illustrated by FIG. 4. A read power source 150 applies an appropriate input (e.g., a selected read voltage) to the memory cell 124. The amount of read current I_{R} that flows through the cell 124 will be a function of the resistance of the cell (R_{L} or R_{H}, respectively). The voltage drop across the memory cell (voltage V_{MC}) is sensed via path 152 by the positive (+) input of a comparator 154. A suitable reference (such as voltage reference V_{REF}) is supplied to the negative (−) input of the comparator 154 from a reference source 156.

The voltage reference V_{REF} can be selected from various embodiments such that the voltage drop V_{MC} across the memory cell 124 will be lower than the V_{REF} value when the resistance of the cell is set to R_{L}, and will be higher than the V_{REF} value when the resistance of the cell is set to R_{H}. In this way, the output voltage level of the comparator 154 will indicate the logical bit value (0 or 1) stored by the memory cell 124.

FIG. 5 displays a programmable metallization memory cell (PMC) 158. A first electrode 160 is connected to a transistor 162 that is activated through a signal from the word line 164. In some embodiments, control circuitry (not shown) could be used to adjust the relative potential between the first and second electrodes 160 and 174. The completion of a circuit allows a current pulse 166 to potentially flow through the PMC 158 to a terminal 168 (or vice versa). With a forward bias through the memory cell 158, a filament 170 is formed in the embedded layer 176 by the migration of ions from the metal layer 172 and electrons from the second electrode 174. A dielectric layer 178 focuses the embedded layer 176 to contain the position of the formed filament 170. Furthermore, the resistive relationship of the embedded layer 178 to the metal layer 172 defines the logical state of the memory cell 158.

FIG. 6 shows a programmable metallization memory cell 158. The memory cell is substantially similar to the cell displayed in FIG. 5, but the reverse bias direction of the current pulse 166 causes the dissipation of the filament 170. The dissipation is facilitated through reversing the polarization of the electrodes and causing the ions to migrate towards the electrodes 160 and 174. In some embodiments, the PMC 158 is constructed in reverse sequence so that the filament forming current pulse and filament dissipating pulse are the reverse of the pulses shown in FIGS. 5 and 6. Likewise, the transistor 162 can be relocated on the PMC 158 so long as a circuit path can be completed through the first and second electrode layers 160 and 174. Further in some embodiments, the direction of the current pulse 166 opposes the migration direction of the metal ions that form the filament 170.

A memory cell 180 operated in accordance with various embodiments of the present invention is generally illustrated in FIG. 7. A first electrode 182 having a first charge is coupled to an ionic region 184 that is also coupled to a second electrode 186 that has a second charge. The activation of a transistor 188 through selection by a word line 190 allows a current 192 to flow through the memory cell 180 to a ground 194 (or vice versa). When the current 192 has a forward bias, ions from the doping layer 196 combine with electrons migrating to the electrolyte layer 198 to form a filament 200. The ions migrating from the doping layer 196 are controlled by the composite layer 202. The ionic region 184 comprises a doping layer 196, an electrolyte layer 198, and a composite layer 202.

It can be appreciated by one skilled in the art that electrolyte layer 198 can comprise a solid state electrolyte material that is ionically conductive. Further, the doping layer 196 can comprise a doped metal rich material. The formation of the memory cell can be defined by, but not limited to, nano-trench, hard mask, or etch post cell material deposition. In addition, a cross-bar or pin contact structure can be utilized to define the memory cell 180.

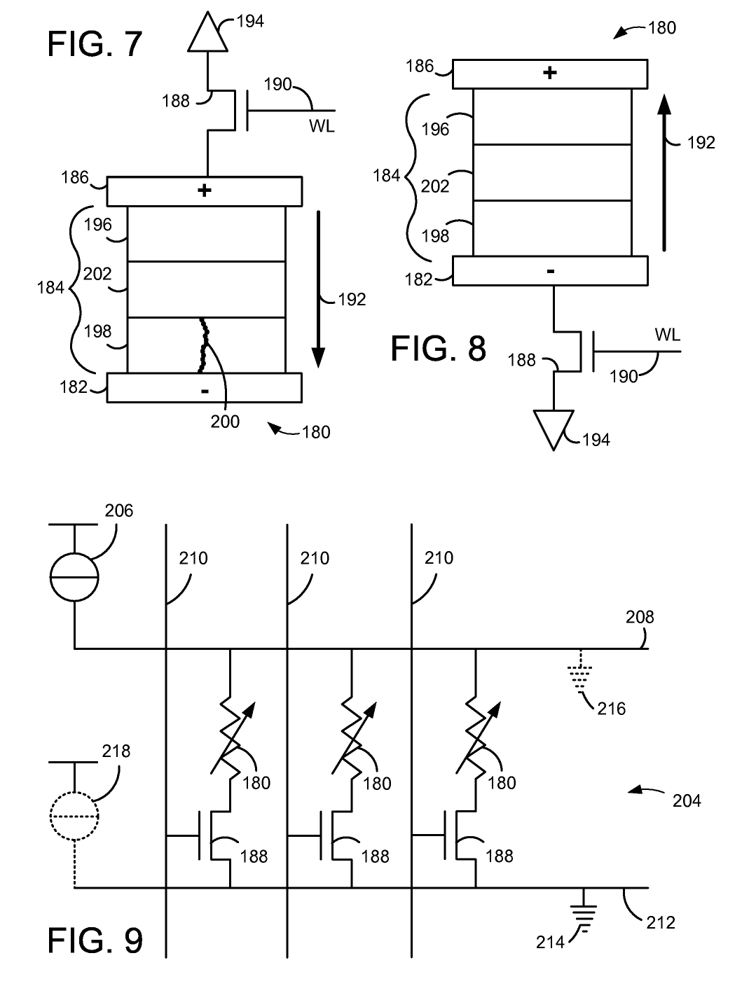

In FIG. 8, a memory cell 180 operated in accordance with various embodiments of the present invention is shown. A current 192 flowing through the memory cell with a reverse bias that opposes the direction displayed in FIG. 7 dissipates the formed filament 200. The flow of current 192 in a reverse direction induces the components that created the filament 200 shown in FIG. 7 to be pulled apart due to the attraction of the ions and electrons away from the electrolyte layer 198 of the ionic region 184.

FIG. 9 illustrates an array of memory cells 204 operated in accordance with various embodiments of the present invention. A first source 206 is connected to a bit line 208. A plurality of memory cells 180 are attached to the bit line 208 to form an array of memory cells. Adjacent to each cell 180 is the transistor 188 of FIGS. 7 and 8 that forms a unit cell and allows power to flow through the memory cell 180. The writing of a logic state to an ionic region 184 of a memory cell 180 with a current pulse from the first source 206 creates a voltage differential between the bit line 208 and the source line 212. The source line 212 has a first ground connection 214 that can be selected to complete a circuit path from the first source 206 to the first ground connection 214 through a memory cell 180. Similarly, a second ground connection 216 is attached to the bit line 208 to complete a circuit path from the second source 218 through a cell 180 to the second ground connection 216.

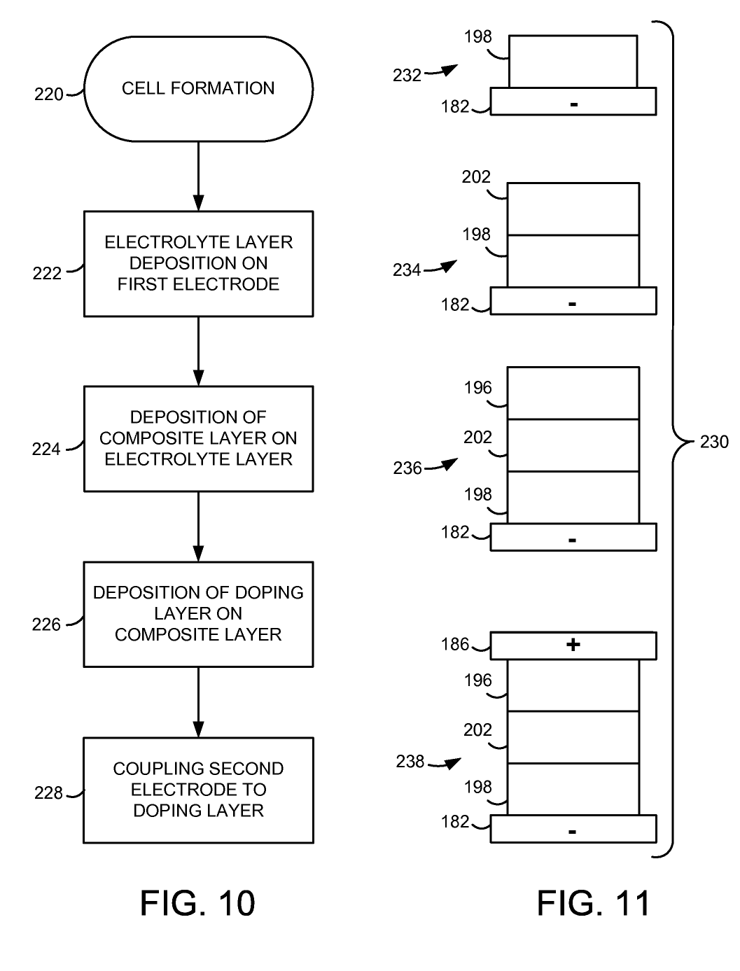

A flow diagram of a cell formation operation 220 performed in accordance with the various embodiments of the present invention is shown in FIG. 10. A cell formation operation 220 begins with depositing an electrolyte layer (198 of FIGS. 7 and 8) onto a first electrode 182 in step 222. Subsequently, step 224 deposits a composite layer 202 adjacent to the electrolyte layer 198. Step 226 involves depositing a doping layer 196 on the composite layer 202. Finally, a second electrode 186 is coupled to the doping layer 196 to form a completed memory cell 180.

FIG. 11 is a graphical representation 230 of the cell formation operation 220 of FIG. 10. Initially, an electrolyte layer 198 is deposited on a first electrode 182 to form a first base 232. In some embodiments, after the electrolyte layer deposition a relatively thicker composite layer 202 can be deposited on top of the electrolyte layer 198 either by co-sputter or by a single target alloy deposition to form a second base 234. The second base 234 can be diffused by applying an ultra-violet (UV) annealing or oxidation if needed. It should be noted that the UV annealing or oxidation is not necessary to embed super ionic materials (i.e. Ag2S, CuS, Ag2Te, CuTe, etc.) into ionic conductive materials (i.e. chalcogenide, or oxidation).

Further in some embodiments, the composite layer 202 is constructed to have a low resistance. A third base 236 is formed by depositing a doping layer 196 on the composite layer 202. For example, in the case of superionic embedded chalcogenide, a doping layer 196 can be deposited in sequence with chalcogenide materials due to the composite layer's low resistance. In the case of superionic or metal doping inside the oxide materials of a composite layer, co-sputtering can be utilized by controlling the ratio of superionic phase to oxide by deposition and the conductive composite layer 202 can be grown directly. In alternative embodiments, a heat treatment or UV application may be undertaken, but is not required. It can be appreciated that various methods can be used to create the composite layer 202; however, the components of the layer must be an electrical conductor initially due to a self-promoted chemical reaction between the layers or by a doping affect. The result of the low resistance state of the composite layer 202 is that the filament 200 shown in FIG. 7 will form in the high resistance electrolyte layer 198 instead of the composite layer 202.

In addition, the function of composite layer 202 is essential to the operation of the memory cell 180. The low resistance state of the composite layer 202 that is different from the resistance of the doping metal in the doping layer 196 effectively regulates the ionic flow from the adjacent doping layer 196 to the electrolyte layer 198. Due to the relative high bonding energy of doping metal ion inside the composite layer 202, it does not supply metal ion as easily as the conventional memory cell 158.

Finally, a memory cell 238 is completed by the coupling of a second electrode layer 186 to the doping layer 196. Furthermore, the separation of the metal ion supply from the filament forming layer lowers the stress associated with the switching rate and cell retention. The electrolyte layer 198 thickness can also be reduced by using high ionically conductive and high breakdown materials while the composite layer 202 regulating the metal ion supply to the electrolyte layer 198.

As can be appreciated by one skilled in the art, the various embodiments illustrated herein provide advantages in both memory cell efficiency and complexity due to the separation of the filament forming layer and the metal ion supply. The regulation of the migration of metal ions from the doping layer 198 to the electrolyte layer 198 provides heightened performance. Moreover, manufacturing accuracy can be greatly improved by reducing the complexity of the filament forming layer. However, it will be appreciated that the various embodiments discussed herein have numerous potential applications and are not limited to a certain field of electronic media or type of data storage devices.

It is to be understood that even though numerous characteristics and advantages of various embodiments of the present invention have been set forth in the foregoing description, together with details of the structure and function of various embodiments of the invention, this detailed description is illustrative only, and changes may be made in detail, especially in matters of structure and arrangements of parts within the principles of the present invention to the full extent indicated by the broad general meaning of the terms in which the appended claims are expressed.

What is claimed is:

1. A memory cell comprising:
a first electrode connected to a source;
a second electrode connected to a ground; and
an ionic region between the first and second electrodes that comprises a doping layer, a composite layer, and an electrolyte layer, wherein the composite layer has a low resistive state and the electrolyte layer switches from a high resistive state to a low resistive state based on the presence of a filament.

2. The memory cell of claim 1, wherein the composite layer comprises an ionic material embedded in a chalcogenide or oxide material.

3. The memory cell of claim 1, wherein the electrolyte layer comprises a solid state electrolyte.

4. The memory cell of claim 2, wherein the ionic material comprises Ag₂S, CuS, Ag₂Te, or CuTe.

5. The memory cell of claim 1, wherein the composite layer regulates an ionic flow from the doping layer to the electrolyte layer and the composite layer is positioned between the doping layer and the electrolyte layer.

6. The memory cell of claim 1, wherein the memory cell is a programmable metallization cell (PMC).

7. The memory cell of claim 1, wherein the electrolyte layer is ionically conductive.

8. The memory cell of claim 1, wherein the doping layer comprises a doped metal.

9. The memory cell of claim 8, wherein the composite layer is embedded with the doped metal.

10. The memory cell of claim 1, wherein the electrolyte layer has a reduced thickness in relation to the composite layer.

11. A method of forming a memory cell comprising depositing an electrolyte layer on a first electrode, coupling a composite layer adjacent to the electrolyte layer, depositing a doping layer onto the composite layer, and coupling a second electrode to the doping layer, wherein the composite layer has a low resistive state and the electrolyte layer switches between a low resistive state and a high resistive state based on the presence of a filament.

12. The method of claim 11, wherein the composite layer comprises a super ionic material embedded in a chalcogenide.

13. The method of claim 11, wherein the composite layer comprises a super ionic material is embedded in an oxide.

14. The method of claim 11, wherein the composite layer is deposited by target alloy deposition.

15. The method of claim 11, wherein the composite layer regulates an ionic flow from the doping layer to the electrolyte layer and the composite layer is positioned between the doping layer and the electrolyte layer.

16. The method of claim 11, wherein the composite layer is diffused by applying an ultra-violet annealing or oxidation step.

17. The method of claim 11, wherein the composite layer is deposited using a co-sputtering technique.

18. The method of claim 11, wherein the doping layer comprises a doped metal.

19. The method of claim 18, wherein the composite layer is embedded with the doped metal.

20. The method of claim 11, wherein the electrolyte layer has a reduced thickness in relation to the composite layer.
